(19) United States
(12) Patent Application Publication
(10) Pub. No.: US 2026/0334295 A1
(43) Pub. Date: Oct. 22, 2026

(54) SEMICONDUCTOR DEVICE

(71) Applicant: Mitsubishi Electric Corporation, Tokyo (JP)

(72) Inventors: Eiko OTSUKI, Tokyo (JP); Masanori TSUKUDA, Tokyo (JP); Hidenori FUJII, Tokyo (JP); Shinya SONEDA, Tokyo (JP); Kazuya KONISHI, Tokyo (JP)

(73) Assignee: Mitsubishi Electric Corporation, Tokyo (JP)

(21) Appl. No.: 19/529,212

(22) Filed: Feb. 4, 2026

(30) Foreign Application Priority Data
Apr. 17, 2025 (JP) 2025-068174

(51) Int. Cl. H10W 74/10; H10D 8/00; H10D 8/60; H10D 12/00; H10D 62/10; H10D 62/83; H10W 74/47

(52) U.S. Cl. CPC H10W 74/137; H10D 62/107; H10D 62/83; H10W 74/147; H10W 74/476; H10D 8/411; H10D 8/60; H10D 12/415

(57) ABSTRACT

A semiconductor device includes: an insulating layer selectively disposed on a semiconductor substrate; a terminal electrode layer that is selectively disposed on the insulating layer, and is connected to an exposed semiconductor portion that is a portion of the semiconductor substrate in a termination region, the exposed semiconductor portion being exposed through the insulating layer; and an organic film that has insulating properties, and is disposed above an exposed insulating portion that is a portion of the insulating layer, the exposed insulating portion being exposed through the terminal electrode layer, wherein an average thickness of the organic film disposed above the exposed insulating portion is greater than 5 μm and smaller than 9 μm.

### BACKGROUND

### Technical Field

The present disclosure relates to a semiconductor device.

### Description of the Background Art

Japanese Patent Application Laid-Open No. 2017-092360 proposes semiconductor device in which an organic film such as a polyimide film or a polybenzoxazole (PBO) film is provided as a protective film in a termination region in which an electrode layer for a pressure-resistant structure such as a field limiting ring (FLR) is provided.

However, in a configuration in which the organic film has a great thickness, there is a problem in that moisture contained in the organic film corrodes the electrode layer during a temperature humidity bias (THB) test at high humidity, for example. On the other hand, in a configuration in which the organic film has a small thickness, there is a problem in that the organic film is damaged by thermal stress, for example.

### SUMMARY

The present disclosure has been made in view of the above problem, and aims to provide a technology that can appropriately provide an organic film.

A semiconductor device according to the present disclosure includes: a semiconductor substrate in which an active region and a termination region adjacent to the active region are defined; an insulating layer selectively disposed on the semiconductor substrate; a terminal electrode layer that is selectively disposed on the insulating layer, and is connected to an exposed semiconductor portion that is a portion of the semiconductor substrate in the termination region, the exposed semiconductor portion being exposed through the insulating layer; and an organic film that has insulating properties, and is disposed above an exposed insulating portion that is a portion of the insulating layer, the exposed insulating portion being exposed through the terminal electrode layer, wherein the average thickness of the organic film disposed above the exposed insulating portion is greater than 5 μm and smaller than 9 μm.

An organic film can be appropriately provided.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view illustrating the configuration of a semiconductor device according to a first preferred embodiment;

FIG. 2 is a cross-sectional view illustrating the configuration of a semiconductor device according to a second preferred embodiment;

FIG. 3 is a cross-sectional view illustrating the configuration of a semiconductor device according to a third preferred embodiment;

FIG. 4 is a cross-sectional view illustrating the configuration of a semiconductor device according to a fourth preferred embodiment;

FIG. 5 is a cross-sectional view illustrating the configuration of a semiconductor device according to a fifth preferred embodiment;

FIG. 6 is a cross-sectional view illustrating the configuration of a semiconductor device according to a sixth preferred embodiment;

FIG. 7 is a cross-sectional view illustrating the configuration of a semiconductor device according to a seventh preferred embodiment;

FIG. 8 is a cross-sectional view illustrating the configuration of a semiconductor device according to an eighth preferred embodiment;

FIG. 9 is a cross-sectional view illustrating the configuration of a semiconductor device according to a ninth preferred embodiment;

FIG. 10 is a cross-sectional view illustrating the configuration of a semiconductor device according to a tenth preferred embodiment;

FIG. 11 is a cross-sectional view illustrating the configuration of a semiconductor device according to an eleventh preferred embodiment;

FIG. 12 is a cross-sectional view illustrating the configuration of a semiconductor device according to a twelfth preferred embodiment;

FIG. 13 is a cross-sectional view illustrating the configuration of a semiconductor device according to a thirteenth preferred embodiment;

FIG. 14 is a cross-sectional view illustrating the configuration of a semiconductor device according to a fourteenth preferred embodiment; and

FIG. 15 is a cross-sectional view illustrating the configuration of a semiconductor device according to a fifteenth preferred embodiment.

### DESCRIPTION OF THE PREFERRED EMBODIMENTS

The following is a description of preferred embodiments, with reference to the accompanying drawings. The features described below in the respective preferred embodiments are examples, and all the features are not necessarily essential. Also, in the description below, similar components in a plurality of preferred embodiments are denoted by the same or similar reference signs, and different components are mainly explained. Further, in the description below, specific positions and directions such as “upper”, “lower”, “left”, “right”, “front”, and “back” do not necessarily match the actual positions and directions in implementation. Furthermore, a fact that a certain portion has a higher concentration than another portion may mean that the average or peak of the concentration at the certain portion is higher than the average or peak of the concentration at another portion. Conversely, a fact that a certain portion has a lower concentration than another portion may mean that the average or peak of the concentration at the certain portion is lower than the average or peak of the concentration at another portion. Further, in the following, the first conductivity type is the p-type, and the second conductivity type is the n-type. However, the first conductivity type may be the n-type, and the second conductivity type may be the p-type.

### First Preferred Embodiment

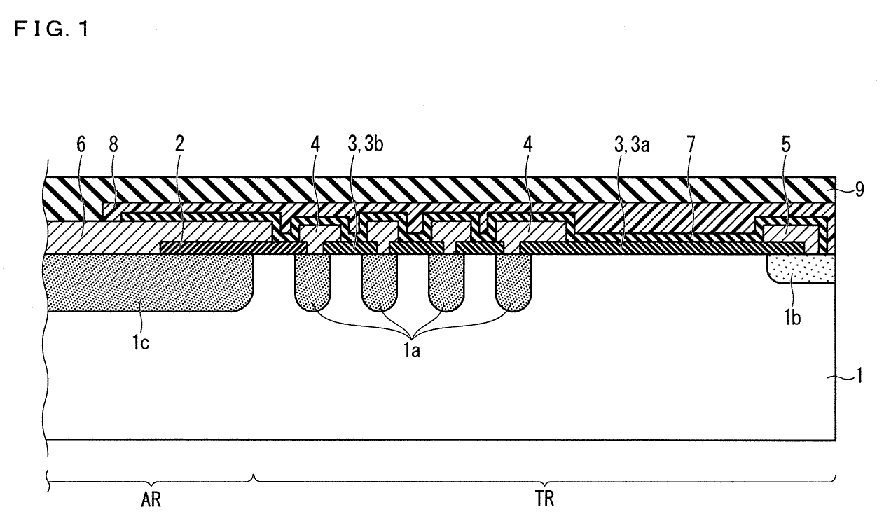

FIG. 1 is a cross-sectional view illustrating the configuration of a semiconductor device according to a first preferred embodiment. The semiconductor device in FIG. 1 includes a semiconductor substrate 1, a first insulating layer 2, a second insulating layer 3, a first terminal electrode layer 4, a second terminal electrode layer 5, a first active electrode layer 6, a nonmetallic film 7, an organic film 8, and a sealing member 9. Note that, in FIG. 1, the first insulating layer 2 and the second insulating layer 3 are included in the insulating layer, but the present disclosure is not limited to this. The first terminal electrode layer 4 and the second terminal electrode layer 5 are included in the terminal electrode layer, but the present disclosure is not limited to this.

In the semiconductor substrate 1, an active region AR and a termination region TR adjacent to the active region AR are defined. A semiconductor element is disposed in the active region AR, and a pressure-resistant structure such as a field limiting ring (FLR) is disposed in the termination region TR. The semiconductor element disposed in the active region AR includes a metal-oxide semiconductor field-effect transistor (MOSFET), an insulated gate bipolar transistor (IGBT), a reverse-conducting-IGBT (RC-IGBT), a Schottky barrier diode (SBD), or a PN junction diode (PND), for example.

The semiconductor substrate 1 in FIG. 1 includes a p-type first semiconductor layer 1a and an n-type second semiconductor layer 1b disposed in the termination region TR, and a p-type third semiconductor layer 1c disposed in the active region AR. The second semiconductor layer 1b is disposed closer to the end portion side (the right side in FIG. 1) of the semiconductor substrate 1 than the first semiconductor layer 1a. Note that, in FIG. 1, the remaining portion of the semiconductor substrate 1 excluding the first semiconductor layer 1a, the second semiconductor layer 1b, and the third semiconductor layer 1c has the n-type conductivity, which is the second conductivity type, and the concentration of the n-type impurities in the second semiconductor layer 1b is higher than the concentration of the n-type impurities in the remaining portion of the semiconductor substrate 1.

The material of the semiconductor substrate 1 includes silicon (Si) or a wide bandgap semiconductor, for example, and the wide bandgap semiconductor includes silicon carbide (SiC), gallium nitride (GaN), gallium oxide (Ga₂O₃), or diamond, for example. In a case where the material of the semiconductor substrate 1 is a wide bandgap semiconductor, it is possible to stably operate the semiconductor device at high temperature and at high voltage, and increase the switching speed. Note that the semiconductor substrate 1 may be formed with a normal semiconductor wafer, or may be formed with an epitaxially grown layer.

The first insulating layer 2 and the second insulating layer 3 are selectively disposed on the semiconductor substrate 1, and have a contact hole partially exposing the semiconductor substrate 1. The second insulating layer 3 is disposed in the termination region TR, and an exposed semiconductor portion that is a portion of the semiconductor substrate 1 in the termination region TR exposed through the second insulating layer 3 includes the first semiconductor layer 1a and the second semiconductor layer 1b. The first insulating layer 2 is disposed over the active region AR and the termination region TR, and a portion of the semiconductor substrate 1 in the active region AR exposed through the first insulating layer 2 includes the third semiconductor layer 1c. Note that the material of the first insulating layer 2 and the second insulating layer 3 includes silicon dioxide, for example.

The first terminal electrode layer 4 and the second terminal electrode layer 5 are electrode layers in the termination region TR, and are selectively disposed on the first insulating layer 2 and the second insulating layer 3. The first terminal electrode layer 4 is electrically connected to the first semiconductor layer 1a included in the exposed semiconductor portion, and the first terminal electrode layer 4 and the first semiconductor layer 1a constitute an FLR, for example. The second terminal electrode layer 5 is electrically connected to the second semiconductor layer 1b included in the exposed semiconductor portion. Note that the material of the first terminal electrode layer 4 and the second terminal electrode layer 5 includes aluminum, for example.

The first active electrode layer 6 is an electrode layer in the active region AR, and is selectively disposed on the first insulating layer 2. The first active electrode layer 6 is electrically connected to the third semiconductor layer 1c exposed through the first insulating layer 2 of the semiconductor substrate 1 in the active region AR. Note that the material of the first active electrode layer 6 includes aluminum, for example. Further, in the following description, in a case where the first terminal electrode layer 4, the second terminal electrode layer 5, and the first active electrode layer 6 are not distinguished from one another, they will be sometimes referred to simply as the “electrode layers”.

The nonmetallic film 7 is provided on the first insulating layer 2, the second insulating layer 3, the first terminal electrode layer 4, the second terminal electrode layer 5, and the first active electrode layer 6. The nonmetallic film 7 may be only a semi-insulating layer such as a silicon nitride film, only an insulating layer such as a nitride film, or a stack structure in which the lower layer is a semi-insulating layer and the upper layer is an insulating layer as in glass coating. Note that, in a case where the nonmetallic film 7 has such a stack structure, the semi-insulating layer can stabilize the electric field and reduce leakage current on the surface of the base (the first insulating layer 2, for example) of the nonmetallic film 7, and the insulating layer can protect the electrode layers and the semi-insulating layer electrically and mechanically.

The material of the organic film 8 includes polyimide or polybenzoxazole (PBO), for example, and has insulating properties. In the first preferred embodiment, the organic film 8 is disposed above exposed insulating portions 3a and 3b that are portions of the second insulating layer 3 exposed through the first terminal electrode layer 4 and the second terminal electrode layer 5. The exposed insulating portion 3a is a portion of the second insulating layer 3 located between the first terminal electrode layer 4 and the second terminal electrode layer 5, and the exposed insulating portion 3b is a portion of the second insulating layer 3 located between the first terminal electrode layers 4. In the first preferred embodiment, the organic film 8 is disposed not only above the exposed insulating portions 3a and 3b but also above the first terminal electrode layer 4, above the second terminal electrode layer 5, and above the first active electrode layer 6, but this is not essential.

The average thickness of the organic film 8 disposed above the exposed insulating portions 3a and 3b is greater than 5 μm and smaller than 9 μm. The average thickness is the average of measurement values obtained by measuring thicknesses in the vertical direction in FIG. 1, with respect to a plurality of portions of the organic film 8, for example.

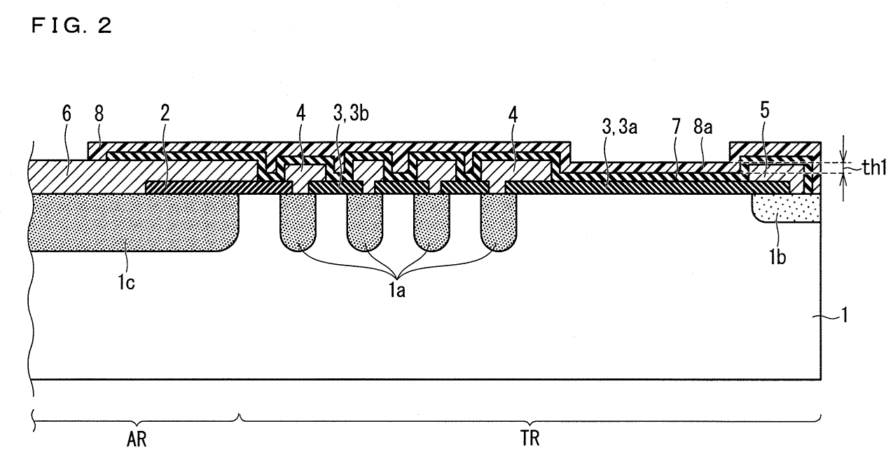

The sealing member 9 covers the organic film 8. The material of the sealing member 9 includes insulating silicone gel or insulating resin, for example, and the resin here includes epoxy resin, for example. Note that, for convenience of the drawings, the sealing member 9 is not shown in FIG. 2 and the subsequent drawings. <Summary of the first preferred embodiment>

In the semiconductor device according to the first preferred embodiment, the average thickness of the organic film 8 disposed above the exposed insulating portions 3a and 3b, which are the portions of the second insulating layer 3 exposed through the first terminal electrode layer 4 and the second terminal electrode layer 5, is greater than 5 μm and smaller than 9 μm. In such a configuration, the average thickness of the organic film 8 is smaller than 9 μm, and thus, it is possible to reduce corrosion of the electrode layers by moisture contained in the organic film 8, and reduce damage to the glass coat of the nonmetallic film 7 or the organic film 8 due to thermal expansion of the moisture, during a temperature humidity bias (THB) test at high humidity. Also, the average thickness of the organic film 8 is greater than 5 μm. Thus, it is possible to reduce damage to the organic film 8 due to thermal stress, and reduce damage to the organic film 8 due to a corner portion of the base of the organic film 8. As described above, according to the first preferred embodiment, the organic film 8 can be appropriately provided.

### Second Preferred Embodiment

FIG. 2 is a cross-sectional view illustrating the configuration of a semiconductor device according to a second preferred embodiment. In the second preferred embodiment, an organic film 8 includes a first organic film portion 8a that is disposed between a first terminal electrode layer 4 and a second terminal electrode layer 5, and has a thickness th1 that is smaller than 6 μm. The other portions of the configuration of the second preferred embodiment are the same as those of the first preferred embodiment. With such a configuration, the thickness of the organic film 8 between the first terminal electrode layer 4 and the second terminal electrode layer 5 can be reduced, and thus, adverse influence of moisture contained in the organic film 8 can be reduced.

### Third Preferred Embodiment

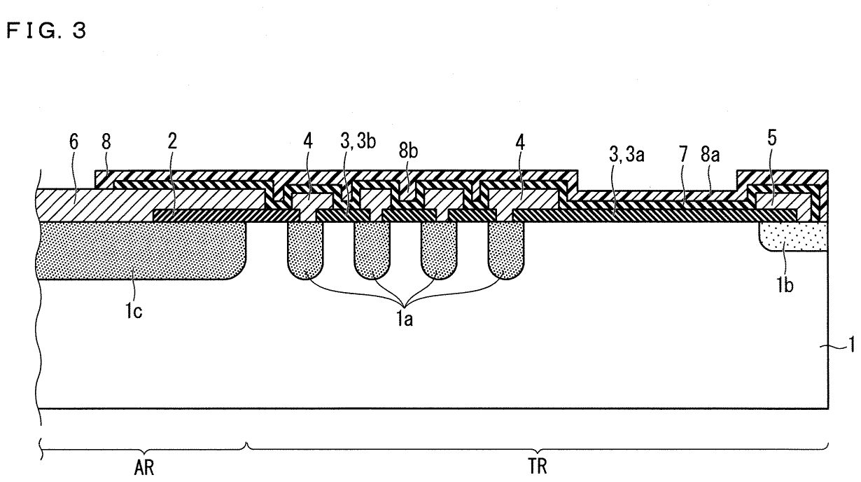

FIG. 3 is a cross-sectional view illustrating the configuration of a semiconductor device according to a third preferred embodiment. In the third preferred embodiment, an organic film 8 includes a first organic film portion 8a disposed between a first terminal electrode layer 4 and a second terminal electrode layer 5, and a second organic film portion 8b other than the first organic film portion 8a. The second organic film portion 8b is a portion disposed between first terminal electrode layers 4 in the organic film 8 as in FIG. 3, for example.

In the third preferred embodiment, the thickness of the first organic film portion 8a is smaller than the thickness of the second organic film portion 8b. The other portions of the configuration of the third preferred embodiment are the same as those of the first preferred embodiment. With such a configuration, the thickness of the organic film 8 between the first terminal electrode layer 4 and the second terminal electrode layer 5 can be reduced, and thus, adverse influence of moisture contained in the organic film 8 can be reduced.

### Fourth Preferred Embodiment

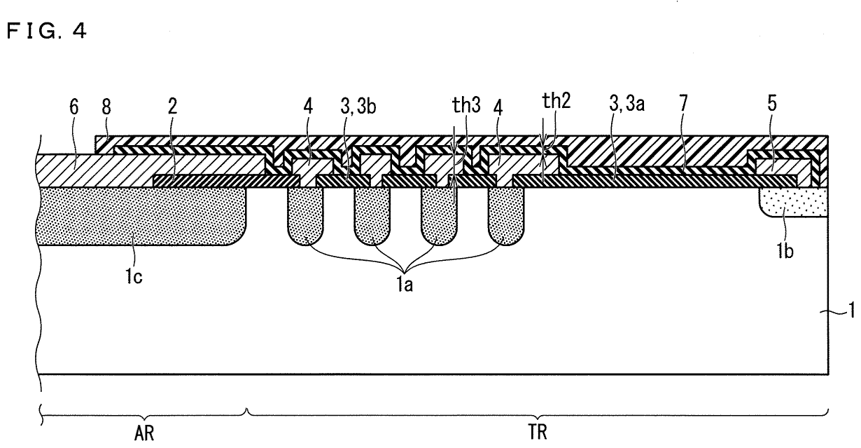

FIG. 4 is a cross-sectional view illustrating the configuration of a semiconductor device according to a fourth preferred embodiment. In the fourth preferred embodiment, a thickness th2 of an organic film 8 disposed above a first terminal electrode layer 4 is equal to or smaller than twice a thickness th3 of the portion of the first terminal electrode layer 4 located on a second insulating layer 3.

The thickness th2 may be smaller than the thickness th3. The above may be applied not only to the first terminal electrode layer 4 but also to a second terminal electrode layer 5. That is, the thickness of the organic film 8 disposed above the second terminal electrode layer 5 may be equal to or smaller than twice the thickness of the portion of the second terminal electrode layer 5 on the second insulating layer 3. The other portions of the configuration of the fourth preferred embodiment are the same as those of the first preferred embodiment. With such a configuration, the thickness th2 of the organic film 8 disposed above the first terminal electrode layer 4 can be made smaller as much as possible, and thus, adverse influence of moisture contained in the organic film 8 can be reduced.

### Fifth Preferred Embodiment

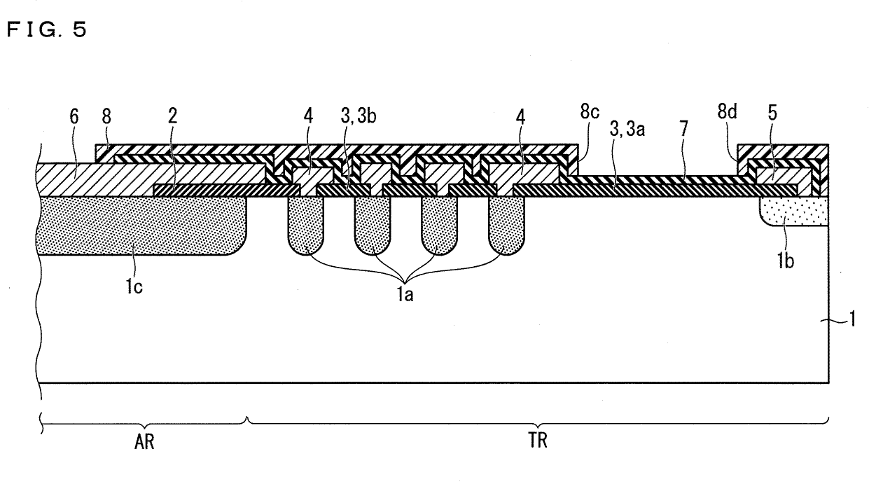

FIG. 5 is a cross-sectional view illustrating the configuration of a semiconductor device according to a fifth preferred embodiment. In the fifth preferred embodiment, an organic film 8 includes a portion 8c covering a side surface of a first terminal electrode layer 4 and a portion 8d covering a side surface of a second terminal electrode layer 5, and the organic film 8 is not disposed between the portion 8c and the portion 8d. That is, the organic film 8 is not disposed between the first terminal electrode layer 4 and the second terminal electrode layer 5, and covers the side surface of the first terminal electrode layer 4 and the side surface of the second terminal electrode layer 5. Although not illustrated in the drawing, the organic film 8 is not necessarily disposed between the first terminal electrode layer 4 and the second terminal electrode layer 5, and does not necessarily cover one or both of a side surface of the first terminal electrode layer 4 and a side surface of the second terminal electrode layer 5. The other portions of the configuration of the fifth preferred embodiment are the same as those of the first preferred embodiment. With such a configuration, the organic film 8 can be reduced, and thus, adverse influence of moisture contained in the organic film 8 can be reduced.

### Sixth Preferred Embodiment

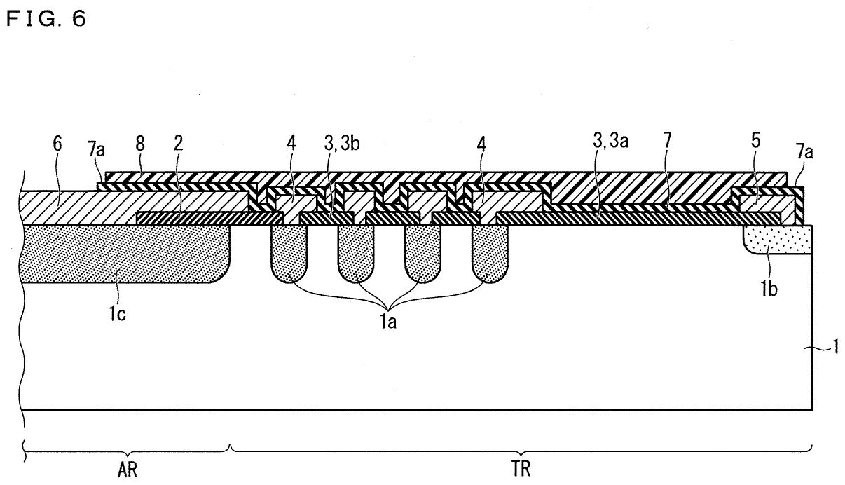

FIG. 6 is a cross-sectional view illustrating the configuration of a semiconductor device according to a sixth preferred embodiment. In the sixth preferred embodiment, an organic film 8 is disposed above exposed insulating portions 3a and 3b, above a first terminal electrode layer 4, above a second terminal electrode layer 5, and above a first active electrode layer 6, as in the first preferred embodiment. Further, a nonmetallic film 7 is disposed between the organic film 8 and each of the exposed insulating portions 3a and 3b, the first terminal electrode layer 4, the second terminal electrode layer 5, and the first active electrode layer 6, with one or two ends 7a of the upper portion of the nonmetallic film 7 being exposed through the organic film 8. The other portions of the configuration of the sixth preferred embodiment are the same as those of the first preferred embodiment. With such a configuration, the organic film 8 can be reduced, and thus, adverse influence of moisture contained in the organic film 8 can be reduced.

### Seventh Preferred Embodiment

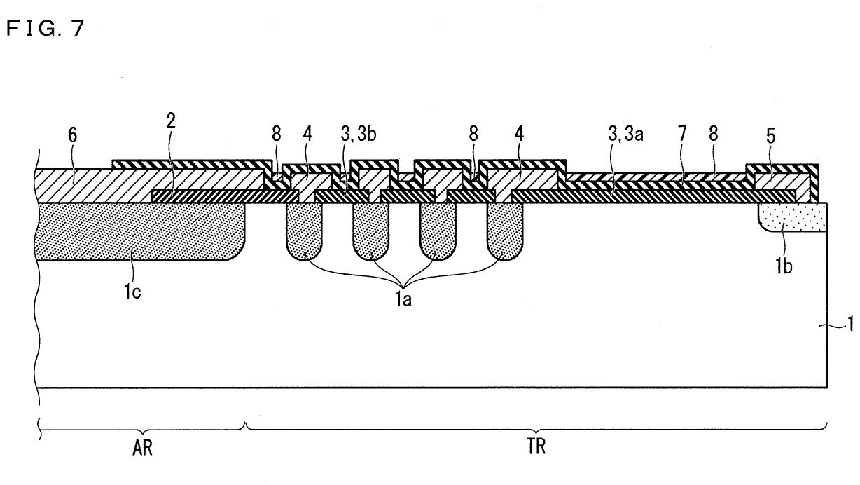

FIG. 7 is a cross-sectional view illustrating the configuration of a semiconductor device according to a seventh preferred embodiment. In the seventh preferred embodiment, an organic film 8 is not disposed above a first terminal electrode layer 4, above a second terminal electrode layer 5, and above a first active electrode layer 6, but is disposed between the first terminal electrode layer 4 and the second terminal electrode layer 5, and between the first terminal electrode layers 4. A side surface of the first terminal electrode layer 4 and a side surface of the second terminal electrode layer 5 are also included between the first terminal electrode layer 4 and the second terminal electrode layer 5, and a side surface of the first terminal electrode layer 4 is also included between the first terminal electrode layers 4. The other portions of the configuration of the seventh preferred embodiment are the same as those of the first preferred embodiment. With such a configuration, the organic film 8 can be reduced, and thus, adverse influence of moisture contained in the organic film 8 can be reduced.

### Eighth Preferred Embodiment

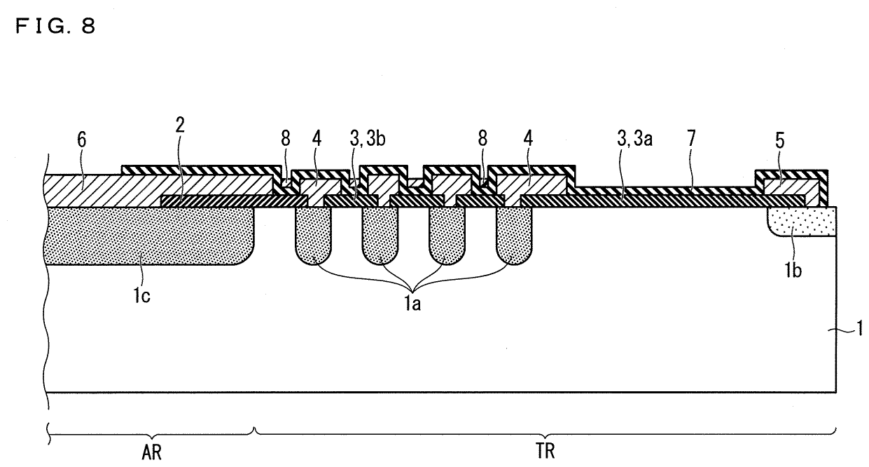

FIG. 8 is a cross-sectional view illustrating the configuration of a semiconductor device according to an eighth preferred embodiment. In the eighth preferred embodiment, an organic film 8 is not disposed between a first terminal electrode layer 4 and a second terminal electrode layer 5. The other portions of the configuration of the eighth preferred embodiment are the same as those of the seventh preferred embodiment. With such a configuration, the organic film 8 can be reduced, and thus, adverse influence of moisture contained in the organic film 8 can be reduced.

### Ninth Preferred Embodiment

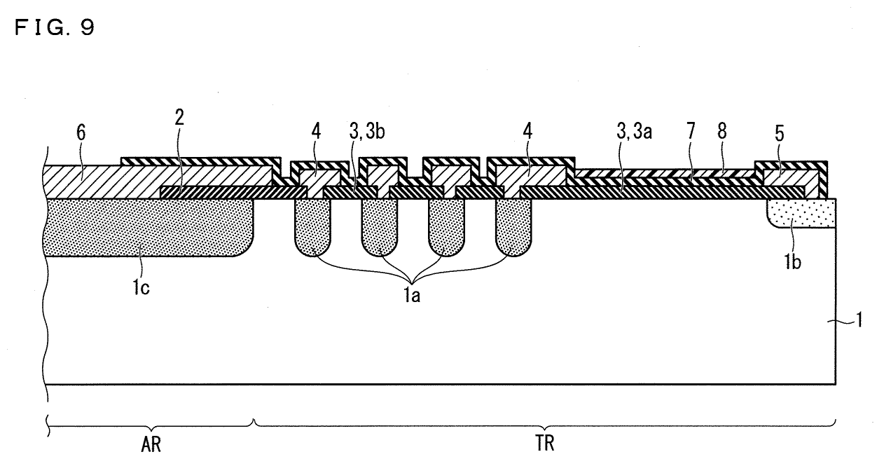

FIG. 9 is a cross-sectional view illustrating the configuration of a semiconductor device according to a ninth preferred embodiment. In the ninth preferred embodiment, an organic film 8 is not disposed between first terminal electrode layers 4, but is disposed only between a first terminal electrode layer 4 and a second terminal electrode layer 5. Note that a side surface of the first terminal electrode layer 4 and a side surface of the second terminal electrode layer 5 are also included between the first terminal electrode layer 4 and the second terminal electrode layer 5. The other portions of the configuration of the ninth preferred embodiment are the same as those of the seventh preferred embodiment. With such a configuration, the organic film 8 can be reduced, and thus, adverse influence of moisture contained in the organic film 8 can be reduced.

### Tenth Preferred Embodiment

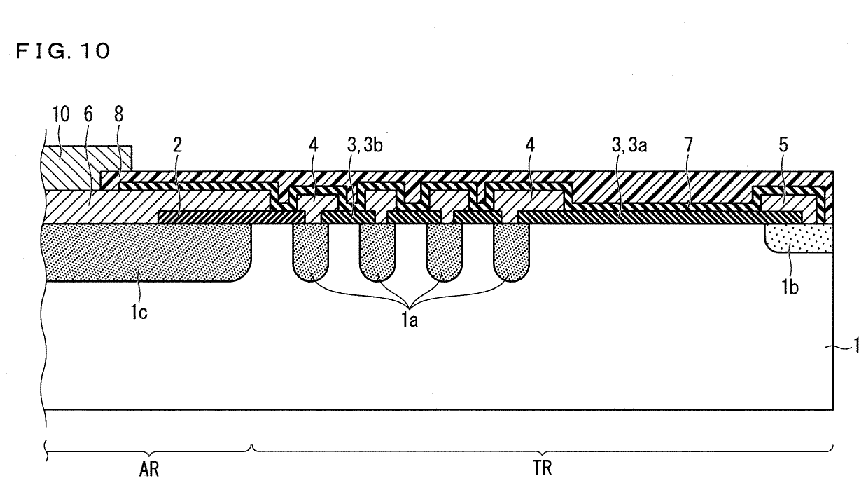

FIG. 10 is a cross-sectional view illustrating the configuration of a semiconductor device according to a tenth preferred embodiment. In the tenth preferred embodiment, an organic film 8 is disposed above exposed insulating portions 3a and 3b, above a first terminal electrode layer 4, above a second terminal electrode layer 5, and above part of a first active electrode layer 6. A second active electrode layer 10 as a plating film is selectively disposed on the organic film 8, and is connected to a remaining portion of the first active electrode layer 6 exposed through the organic film 8. The material of the second active electrode layer 10 contains copper, for example. The other portions of the configuration of the tenth preferred embodiment are the same as those of the first preferred embodiment. With such a configuration, mountability of the semiconductor device can be enhanced by the second active electrode layer 10, which is a plating film.

### Eleventh Preferred Embodiment

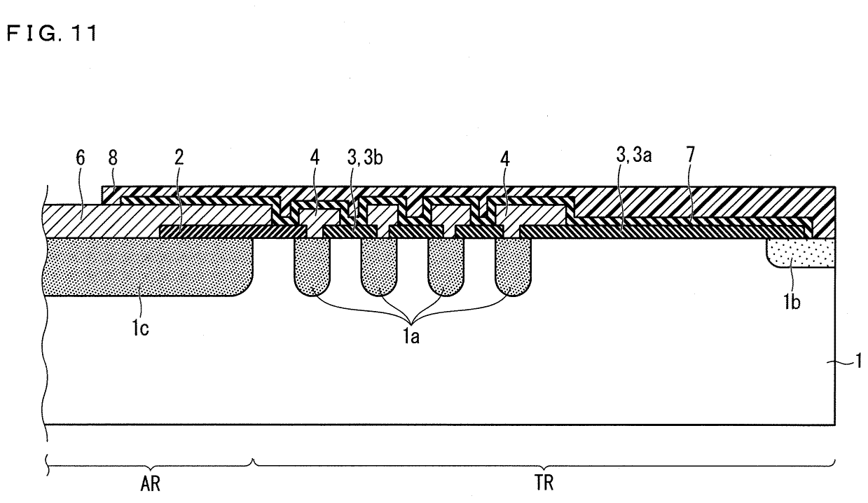

FIG. 11 is a cross-sectional view illustrating the configuration of a semiconductor device according to an eleventh preferred embodiment. In the eleventh preferred embodiment, the terminal electrode layer includes the first terminal electrode layer 4 shown in FIG. 1, which is connected to the first semiconductor layer 1a, but does not include the second terminal electrode layer 5 shown in FIG. 1, which is connected to the second semiconductor layer 1b. That is, the second terminal electrode layer 5 is not provided. The other portions of the configuration of the eleventh preferred embodiment are the same as those of the first preferred embodiment. With such a configuration, the step formed by the second terminal electrode layer 5 is eliminated, and thus, damage to the nonmetallic film 7 and the organic film 8 due to the step can be prevented.

### Twelfth Preferred Embodiment

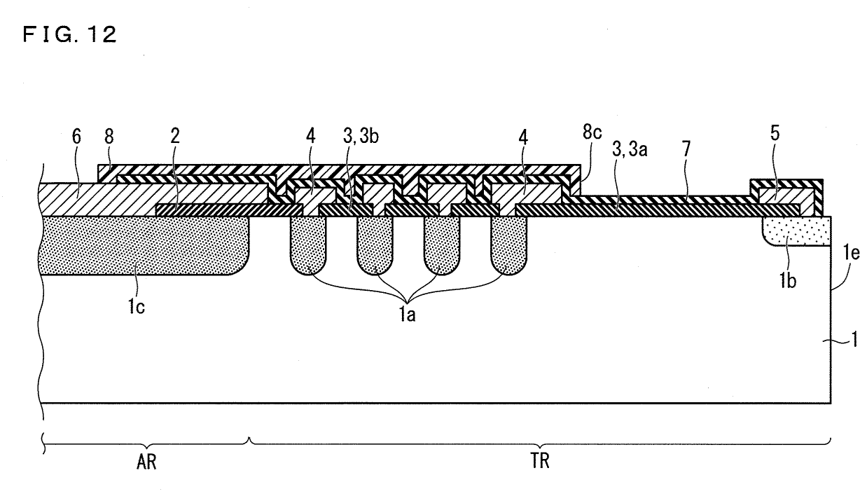

FIG. 12 is a cross-sectional view illustrating the configuration of a semiconductor device according to a twelfth preferred embodiment. In the twelfth preferred embodiment, an organic film 8 does not include the portion 8d shown in FIG. 5 but includes the portion 8c, and the organic film 8 is not disposed between the portion 8c and an end portion 1e of a semiconductor substrate 1. That is, the organic film 8 is not disposed between the first terminal electrode layer 4 and the end portion 1e of the semiconductor substrate 1, and covers a side surface of the first terminal electrode layer 4. Although not illustrated in the drawing, the organic film 8 is not disposed between the first terminal electrode layer 4 and the end portion 1e of the semiconductor substrate 1, and does not necessarily cover a side surface of the first terminal electrode layer 4. The other portions of the configuration of the twelfth preferred embodiment are the same as those of the first preferred embodiment. With such a configuration, the organic film 8 can be reduced, and thus, adverse influence of moisture contained in the organic film 8 can be reduced.

### Thirteenth Preferred Embodiment

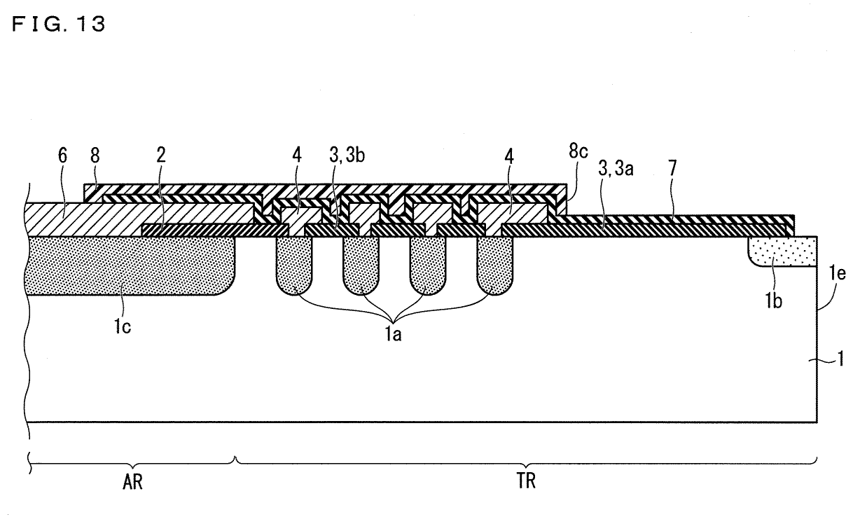

FIG. 13 is a cross-sectional view illustrating the configuration of a semiconductor device according to a thirteenth preferred embodiment. In the thirteenth preferred embodiment, the terminal electrode layer includes the first terminal electrode layer 4 shown in FIG. 1, which is connected to the first semiconductor layer 1a, but does not include the second terminal electrode layer 5 shown in FIG. 1, which is connected to the second semiconductor layer 1b. That is, the second terminal electrode layer 5 is not provided. The other portions of the configuration of the thirteenth preferred embodiment are the same as those of the twelfth preferred embodiment. With such a configuration, the step formed by the second terminal electrode layer 5 is eliminated, and thus, damage to the nonmetallic film 7 due to the step can be prevented.

### Fourteenth Preferred Embodiment

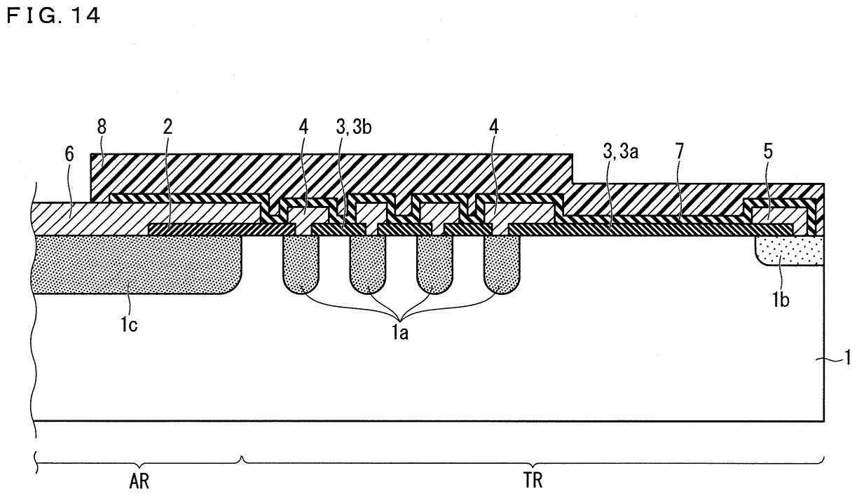

FIG. 14 is a cross-sectional view illustrating the configuration of a semiconductor device according to a fourteenth preferred embodiment. In the fourteenth preferred embodiment, an organic film 8 is disposed above exposed insulating portions 3a and 3b, above a first terminal electrode layer 4, above a second terminal electrode layer 5, and above a first active electrode layer 6, as in the first preferred embodiment. Further, the average thickness of the organic film 8 disposed above the first terminal electrode layer 4 and the first active electrode layer 6 is 9 μm or greater. The average thickness is the average of measurement values obtained by measuring thicknesses in the vertical direction in FIG. 14, with respect to a plurality of portions of the organic film 8, for example. The other portions of the configuration of the fourteenth preferred embodiment are the same as those of the first preferred embodiment. With such a configuration, damage to the organic film 8 or the like due to thermal stress can be reduced.

### Fifteenth Preferred Embodiment

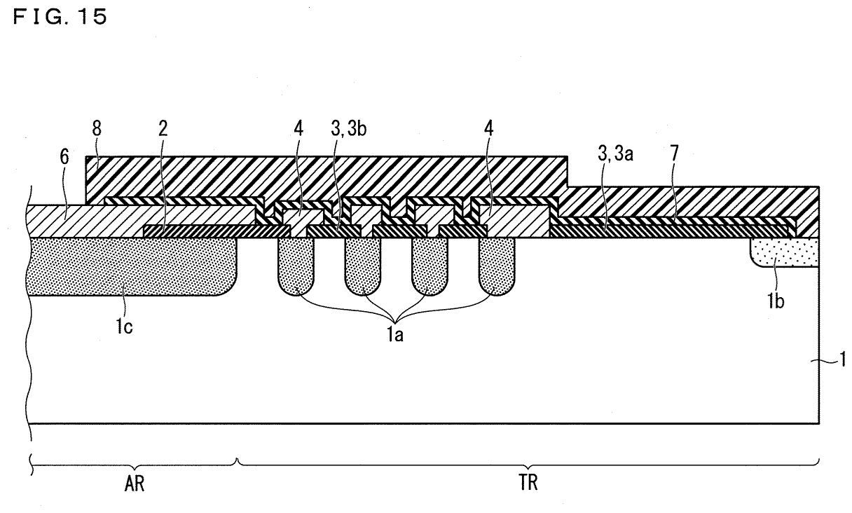

FIG. 15 is a cross-sectional view illustrating the configuration of a semiconductor device according to a fifteenth preferred embodiment. In the fifteenth preferred embodiment, the terminal electrode layer includes the first terminal electrode layer 4 shown in FIG. 1, which is connected to the first semiconductor layer 1a, but does not include the second terminal electrode layer 5 shown in FIG. 1, which is connected to the second semiconductor layer 1b. That is, the second terminal electrode layer 5 is not provided. The other portions of the configuration of the fifteenth preferred embodiment are the same as those of the fourteenth preferred embodiment. With such a configuration, the step formed by the second terminal electrode layer 5 is eliminated, and thus, damage to the organic film 8 and the nonmetallic film 7 due to the step can be prevented.

Note that, in the present disclosure in English, “a” and “an” each mean “one or more”. Accordingly, “a”, “an”, “one or more”, and “at least one” can be used interchangeably.

Note that each preferred embodiment and each modification can be freely combined, and each preferred embodiment and each modification can be modified or omitted as appropriate.

In the following, various modes of the present disclosure are collectively described as Appendixes.

### Appendix 1

A semiconductor device comprising:
a semiconductor substrate in which an active region and a termination region adjacent to the active region are defined;
an insulating layer selectively disposed on the semiconductor substrate;
a terminal electrode layer that is selectively disposed on the insulating layer, and is connected to an exposed semiconductor portion that is a portion of the semiconductor substrate in the termination region, the exposed semiconductor portion being exposed through the insulating layer; and
an organic film that has insulating properties, and is disposed above an exposed insulating portion that is a portion of the insulating layer, the exposed insulating portion being exposed through the terminal electrode layer,
wherein an average thickness of the organic film disposed above the exposed insulating portion is greater than 5 μm and smaller than 9 μm.

### Appendix 2

The semiconductor device according to Appendix 1, wherein
the organic film is disposed above the exposed insulating portion and above the terminal electrode layer.

### Appendix 3

The semiconductor device according to Appendix 2, wherein
the exposed semiconductor portion includes a first semiconductor layer of a first conductivity type, and a second semiconductor layer of a second conductivity type disposed closer to an end portion of the semiconductor substrate than the first semiconductor layer,
the terminal electrode layer includes a first terminal electrode layer connected to the first semiconductor layer, and a second terminal electrode layer connected to the second semiconductor layer, and
the organic film includes a first organic film portion that is disposed between the first terminal electrode layer and the second terminal electrode layer, and has a thickness smaller than 6 μm.

### Appendix 4

The semiconductor device according to Appendix 2, wherein
the exposed semiconductor portion includes a first semiconductor layer of a first conductivity type, and a second semiconductor layer of a second conductivity type disposed closer to an end portion of the semiconductor substrate than the first semiconductor layer,
the terminal electrode layer includes a first terminal electrode layer connected to the first semiconductor layer, and a second terminal electrode layer connected to the second semiconductor layer,
the organic film includes a first organic film portion disposed between the first terminal electrode layer and the second terminal electrode layer, and a second organic film portion that is other than the first organic film portion, and
a thickness of the first organic film portion is smaller than a thickness of the second organic film portion.

### Appendix 5

The semiconductor device according to any one of Appendixes 2 to 4, wherein
a thickness of the organic film disposed above the terminal electrode layer is not greater than twice a thickness of a portion of the terminal electrode layer on the insulating layer.

### Appendix 6

The semiconductor device according to Appendix 2, wherein
the exposed semiconductor portion includes a first semiconductor layer of a first conductivity type, and a second semiconductor layer of a second conductivity type disposed closer to an end portion of the semiconductor substrate than the first semiconductor layer,
the terminal electrode layer includes a first terminal electrode layer connected to the first semiconductor layer, and a second terminal electrode layer connected to the second semiconductor layer, and
the organic film is not disposed between the first terminal electrode layer and the second terminal electrode layer, covers or does not cover a side surface of the first terminal electrode layer, and covers or does not cover a side surface of the second terminal electrode layer.

### Appendix 7

The semiconductor device according to any one of Appendixes 2 to 6, further comprising a first active electrode layer that is selectively disposed on the insulating layer, and is connected to a portion of the semiconductor substrate in the active region, the portion being exposed through the insulating layer,
wherein
the organic film is disposed above the exposed insulating portion, above the terminal electrode layer, and above the first active electrode layer, and
the semiconductor device further comprises a nonmetallic film disposed between the organic film and each of the exposed insulating portion, the terminal electrode layer, and the first active electrode layer, with an upper end of the nonmetallic film being exposed through the organic film.

### Appendix 8

The semiconductor device according to Appendix 1, wherein
the organic film is not disposed above the terminal electrode layer.

### Appendix 9

The semiconductor device according to Appendix 8, wherein
the exposed semiconductor portion includes a first semiconductor layer of a first conductivity type, and a second semiconductor layer of a second conductivity type disposed closer to an end portion of the semiconductor substrate than the first semiconductor layer,
the terminal electrode layer includes a first terminal electrode layer connected to the first semiconductor layer, and a second terminal electrode layer connected to the second semiconductor layer, and
the organic film is not disposed between the first terminal electrode layer and the second terminal electrode layer.

### Appendix 10

The semiconductor device according to Appendix 8, wherein
the exposed semiconductor portion includes a first semiconductor layer of a first conductivity type, and a second semiconductor layer of a second conductivity type disposed closer to an end portion of the semiconductor substrate than the first semiconductor layer,
the terminal electrode layer includes a first terminal electrode layer connected to the first semiconductor layer, and a second terminal electrode layer connected to the second semiconductor layer, and
the organic film is disposed only between the first terminal electrode layer and the second terminal electrode layer.

### Appendix 11

The semiconductor device according to any one of Appendixes 2 to 6, further comprising a first active electrode layer that is selectively disposed on the insulating layer, and is connected to a portion of the semiconductor substrate in the active region, the portion being exposed through the insulating layer,
wherein
the organic film is disposed above the exposed insulating portion, above the terminal electrode layer, and above part of the first active electrode layer, and
the semiconductor device further comprises a second active electrode layer that is a plating film that is selectively disposed on the organic film, and is connected to a remaining portion of the first active electrode layer, the remaining portion being exposed through the organic film.

### Appendix 12

The semiconductor device according to Appendix 2, wherein
the exposed semiconductor portion includes a first semiconductor layer of a first conductivity type, and a second semiconductor layer of a second conductivity type disposed closer to an end portion of the semiconductor substrate than the first semiconductor layer, and
the terminal electrode layer includes a first terminal electrode layer connected to the first semiconductor layer, and does not include a second terminal electrode layer connected to the second semiconductor layer.

### Appendix 13

The semiconductor device according to Appendix 2, wherein
the exposed semiconductor portion includes a first semiconductor layer of a first conductivity type, and a second semiconductor layer of a second conductivity type disposed closer to an end portion of the semiconductor substrate than the first semiconductor layer,
the terminal electrode layer includes a first terminal electrode layer connected to the first semiconductor layer, and a second terminal electrode layer connected to the second semiconductor layer, and
the organic film is not disposed between the first terminal electrode layer and the end portion of the semiconductor substrate, and covers or does not cover a side surface of the first terminal electrode layer.

### Appendix 14

The semiconductor device according to Appendix 2, wherein
the exposed semiconductor portion includes a first semiconductor layer of a first conductivity type, and a second semiconductor layer of a second conductivity type disposed closer to an end portion of the semiconductor substrate than the first semiconductor layer,
the terminal electrode layer includes a first terminal electrode layer connected to the first semiconductor layer, and does not include a second terminal electrode layer connected to the second semiconductor layer, and
the organic film is not disposed between the first terminal electrode layer and the end portion of the semiconductor substrate, and covers or does not cover a side surface of the first terminal electrode layer.

### Appendix 15

The semiconductor device according to Appendix 2, further comprising a first active electrode layer that is selectively disposed on the insulating layer, and is connected to a portion of the semiconductor substrate in the active region, the portion being exposed through the insulating layer,
wherein
the exposed semiconductor portion includes a first semiconductor layer of a first conductivity type,
the terminal electrode layer includes a first terminal electrode layer connected to the first semiconductor layer,
the organic film is disposed above the exposed insulating portion, above the first terminal electrode layer, and above the first active electrode layer, and
an average thickness of the organic film disposed above the first terminal electrode layer and the first active electrode layer is not smaller than 9 μm.

### Appendix 16

The semiconductor device according to Appendix 15, wherein
the exposed semiconductor portion further includes a second semiconductor layer of a second conductivity type disposed closer to an end portion of the semiconductor substrate than the first semiconductor layer, and
the terminal electrode layer includes a first terminal electrode layer connected to the first semiconductor layer, and does not include a second terminal electrode layer connected to the second semiconductor layer.

### Appendix 17

The semiconductor device according to any one of Appendixes 1 to 16, further comprising a sealing member that covers the organic film,
wherein a material of the sealing member includes insulating silicone gel or insulating resin.

### Appendix 18

The semiconductor device according to any one of Appendixes 1 to 17, wherein a material of the semiconductor substrate includes silicon or a wide bandgap semiconductor.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor substrate in which an active region and a termination region adjacent to the active region are defined;
an insulating layer selectively disposed on the semiconductor substrate;
a terminal electrode layer that is selectively disposed on the insulating layer, and is connected to an exposed semiconductor portion that is a portion of the semiconductor substrate in the termination region, the exposed semiconductor portion being exposed through the insulating layer; and
an organic film that has insulating properties, and is disposed above an exposed insulating portion that is a portion of the insulating layer, the exposed insulating portion being exposed through the terminal electrode layer,
wherein an average thickness of the organic film disposed above the exposed insulating portion is greater than 5 μm and smaller than 9 μm.

2. The semiconductor device according to claim 1, wherein
the organic film is disposed above the exposed insulating portion and above the terminal electrode layer.

3. The semiconductor device according to claim 2, wherein
the exposed semiconductor portion includes a first semiconductor layer of a first conductivity type, and a second semiconductor layer of a second conductivity type disposed closer to an end portion of the semiconductor substrate than the first semiconductor layer,
the terminal electrode layer includes a first terminal electrode layer connected to the first semiconductor layer, and a second terminal electrode layer connected to the second semiconductor layer, and
the organic film includes a first organic film portion that is disposed between the first terminal electrode layer and the second terminal electrode layer, and has a thickness smaller than 6 μm.

4. The semiconductor device according to claim 2, wherein
the exposed semiconductor portion includes a first semiconductor layer of a first conductivity type, and a second semiconductor layer of a second conductivity type disposed closer to an end portion of the semiconductor substrate than the first semiconductor layer,
the terminal electrode layer includes a first terminal electrode layer connected to the first semiconductor layer, and a second terminal electrode layer connected to the second semiconductor layer,
the organic film includes a first organic film portion disposed between the first terminal electrode layer and the second terminal electrode layer, and a second organic film portion that is other than the first organic film portion, and
a thickness of the first organic film portion is smaller than a thickness of the second organic film portion.

5. The semiconductor device according to claim 2, wherein
a thickness of the organic film disposed above the terminal electrode layer is not greater than twice a thickness of a portion of the terminal electrode layer on the insulating layer.

6. The semiconductor device according to claim 2, wherein
the exposed semiconductor portion includes a first semiconductor layer of a first conductivity type, and a second semiconductor layer of a second conductivity type disposed closer to an end portion of the semiconductor substrate than the first semiconductor layer,
the terminal electrode layer includes a first terminal electrode layer connected to the first semiconductor layer, and a second terminal electrode layer connected to the second semiconductor layer, and
the organic film is not disposed between the first terminal electrode layer and the second terminal electrode layer, covers or does not cover a side surface of the first terminal electrode layer, and covers or does not cover a side surface of the second terminal electrode layer.

7. The semiconductor device according to claim 2, further comprising a first active electrode layer that is selectively disposed on the insulating layer, and is connected to a portion of the semiconductor substrate in the active region, the portion being exposed through the insulating layer,
wherein
the organic film is disposed above the exposed insulating portion, above the terminal electrode layer, and above the first active electrode layer, and
the semiconductor device further comprises a nonmetallic film disposed between the organic film and each of the exposed insulating portion, the terminal electrode layer, and the first active electrode layer, with an upper end of the nonmetallic film being exposed through the organic film.

8. The semiconductor device according to claim 1, wherein
the organic film is not disposed above the terminal electrode layer.

9. The semiconductor device according to claim 8, wherein
the exposed semiconductor portion includes a first semiconductor layer of a first conductivity type, and a second semiconductor layer of a second conductivity type disposed closer to an end portion of the semiconductor substrate than the first semiconductor layer,
the terminal electrode layer includes a first terminal electrode layer connected to the first semiconductor layer, and a second terminal electrode layer connected to the second semiconductor layer, and
the organic film is not disposed between the first terminal electrode layer and the second terminal electrode layer.

10. The semiconductor device according to claim 8, wherein
the exposed semiconductor portion includes a first semiconductor layer of a first conductivity type, and a second semiconductor layer of a second conductivity type disposed closer to an end portion of the semiconductor substrate than the first semiconductor layer,
the terminal electrode layer includes a first terminal electrode layer connected to the first semiconductor layer, and a second terminal electrode layer connected to the second semiconductor layer, and
the organic film is disposed only between the first terminal electrode layer and the second terminal electrode layer.

11. The semiconductor device according to claim 2, further comprising a first active electrode layer that is selectively disposed on the insulating layer, and is connected to a portion of the semiconductor substrate in the active region, the portion being exposed through the insulating layer,
wherein
the organic film is disposed above the exposed insulating portion, above the terminal electrode layer, and above part of the first active electrode layer, and
the semiconductor device further comprises a second active electrode layer that is a plating film that is selectively disposed on the organic film, and is connected to a remaining portion of the first active electrode layer, the remaining portion being exposed through the organic film.

12. The semiconductor device according to claim 2, wherein
the exposed semiconductor portion includes a first semiconductor layer of a first conductivity type, and a second semiconductor layer of a second conductivity type disposed closer to an end portion of the semiconductor substrate than the first semiconductor layer, and
the terminal electrode layer includes a first terminal electrode layer connected to the first semiconductor layer, and does not include a second terminal electrode layer connected to the second semiconductor layer.

13. The semiconductor device according to claim 2, wherein
the exposed semiconductor portion includes a first semiconductor layer of a first conductivity type, and a second semiconductor layer of a second conductivity type disposed closer to an end portion of the semiconductor substrate than the first semiconductor layer,
the terminal electrode layer includes a first terminal electrode layer connected to the first semiconductor layer, and a second terminal electrode layer connected to the second semiconductor layer, and
the organic film is not disposed between the first terminal electrode layer and the end portion of the semiconductor substrate, and covers or does not cover a side surface of the first terminal electrode layer.

14. The semiconductor device according to claim 2, wherein
the exposed semiconductor portion includes a first semiconductor layer of a first conductivity type, and a second semiconductor layer of a second conductivity type disposed closer to an end portion of the semiconductor substrate than the first semiconductor layer,
the terminal electrode layer includes a first terminal electrode layer connected to the first semiconductor layer, and does not include a second terminal electrode layer connected to the second semiconductor layer, and
the organic film is not disposed between the first terminal electrode layer and the end portion of the semiconductor substrate, and covers or does not cover a side surface of the first terminal electrode layer.

15. The semiconductor device according to claim 2, further comprising a first active electrode layer that is selectively disposed on the insulating layer, and is connected to a portion of the semiconductor substrate in the active region, the portion being exposed through the insulating layer,
wherein
the exposed semiconductor portion includes a first semiconductor layer of a first conductivity type,
the terminal electrode layer includes a first terminal electrode layer connected to the first semiconductor layer,
the organic film is disposed above the exposed insulating portion, above the first terminal electrode layer, and above the first active electrode layer, and
an average thickness of the organic film disposed above the first terminal electrode layer and the first active electrode layer is not smaller than 9 μm.

16. The semiconductor device according to claim 15, wherein
the exposed semiconductor portion further includes a second semiconductor layer of a second conductivity type disposed closer to an end portion of the semiconductor substrate than the first semiconductor layer, and
the terminal electrode layer includes a first terminal electrode layer connected to the first semiconductor layer, and does not include a second terminal electrode layer connected to the second semiconductor layer.

17. The semiconductor device according to claim 1, further comprising a sealing member that covers the organic film,
wherein a material of the sealing member includes insulating silicone gel or insulating resin.

18. The semiconductor device according to claim 1, wherein
a material of the semiconductor substrate includes silicon or a wide bandgap semiconductor.
